(19) United States
(12) Patent Application Publication
(10) Pub. No.: US 2018/0144811 A1
(43) Pub. Date: May 24, 2018

(54) SHIFT REGISTER UNITS, GATE DRIVING CIRCUIT AND DRIVING METHODS THEREOF, AND DISPLAY APPARATUS

(71) Applicants: BOE TECHNOLOGY GROUP CO., LTD., Beijing (CN); Ordos Yuansheng Optoelectronics Co., Ltd., Ordos, Inner Mongolia (CN)

(72) Inventors: Long Han, Beijing (CN); Libin Liu, Beijing (CN)

(21) Appl. No.: 15/574,465

(22) PCT Filed: Apr. 19, 2017
(86) PCT No.: PCT/CN2017/081023

§ 371 Date: Nov. 15, 2017

(30) Foreign Application Priority Data
May 11, 2016 (CN) 201610311714.3

(51) Int. Cl. G11C 19/28; G09G 3/296; G09G 3/3233

(52) U.S. Cl. CPC G11C 19/287; G09G 2310/0286; G09G 3/3233; G09G 3/296

(57) ABSTRACT

Embodiments of the present disclosure provide a shift register unit, a gate driving circuit and driving method thereof, and a display apparatus. The shift register unit comprises a first controlling sub-circuit, a second controlling sub-circuit, a first pulling up sub-circuit, a second pulling up sub-circuit, a first pulling down sub-circuit and a second pulling down sub-circuit. The first controlling sub-circuit controls the potential at the first node. The voltage of a second clock signal terminal can be outputted to the first and the second outputting terminals by the first and the second pulling down sub-circuits, respectively. The first node, the first clock signal terminal and the second voltage terminal may control the potential at a second node through the second controlling sub-circuit. Under the control of the potential at the second node, the voltage of the second voltage terminal can be outputted to the first and the second outputting terminals.

### CROSS-REFERENCE TO RELATED APPLICATION(S)

The present application is a Section 371 National Stage Application of International Application No. PCT/CN2017/081023, which claims priority to the Chinese Patent Application No. 201610311714.3, filed on May 11, 2016, which is incorporated herein by reference in its entirety.

### TECHNICAL FIELD

The present disclosure relates to the field of display technology, and more particularly, to a shift register unit, a gate driving circuit and driving method thereof, and a display apparatus.

### BACKGROUND

Thin film transistor liquid crystal display (TFT-LCD) and active matrix driving OLED (AMOLED) display devices have been widely used in high-performance display fields. The display devices are generally provided with a gate driver on array (GOA) circuit including a plurality of shift register units. Each stage of shift register unit may have an outputting terminal connected to a row of gate lines, so as to output a gate scanning signal to the gate lines, thereby performing a progressive scanning on the gate lines. In addition, other shift register units other than the last stage of shift register unit is required to have its outputting terminal connected to an inputting terminal of its next stage of shift register unit.

However, when some stage of shift register unit in the GOA circuit is broken, the output of other stages of shift register units may be affected, causing a display panel to operate in an abnormal state.

### SUMMARY

According to one aspect of embodiments of the disclosure, a shift register unit is provided. The shift register unit may comprise: a first controlling sub-circuit, connected to a signal inputting terminal, a first clock signal terminal and a first node, and configured to output a voltage at the signal inputting terminal to the first node, under the control of a potential at the first clock signal terminal; a second controlling sub-circuit, connected to the first clock signal terminal, a first voltage terminal, the first node and a second node, and configured to output a voltage at the first voltage terminal to the second node under the control of a potential at the first clock signal terminal, and/or output a voltage at the first clock signal terminal to the second node under the control of a potential at the first node; a first pulling up sub-circuit, connected to the second node, a second voltage terminal and a first signal outputting terminal, and configured to output a voltage at the second voltage terminal to the first signal outputting terminal under the control of a potential at the second node; a second pulling up sub-circuit, connected to the second node, the second voltage terminal and a second signal outputting terminal, and configured to output a voltage at the second voltage terminal to the second signal outputting terminal under the control of a potential at the second node; a first pulling down sub-circuit, connected to the first node, a second clock signal terminal and the first signal outputting terminal, and configured to output a voltage at the second clock signal terminal to the first signal outputting terminal under the control of a potential at the first node; and a second pulling down sub-circuit, connected to the first node, the second clock signal terminal and the second signal outputting terminal, and configured to output a voltage at the second clock signal terminal to the second signal outputting terminal under the control of a potential at the first node.

As an example, the first controlling sub-circuit may comprise a first transistor having a gate connected to the first clock signal terminal, a first terminal connected to the signal inputting terminal, and a second terminal connected to the first node.

As another example, the second controlling sub-circuit may comprise a second transistor and a third transistor, wherein: the second transistor has a gate connected to the first node, a first terminal connected to the first clock signal terminal and a second terminal connected to the second node; and the third transistor has a gate connected to the first clock signal terminal, a first terminal connected to the first voltage terminal and a second terminal connected to the second node.

As another example, the first pulling up sub-circuit comprises a fourth transistor and a first capacitor, wherein the fourth transistor has a gate connected to the second node, a first terminal connected to the second voltage terminal and a second terminal connected to the first signal outputting terminal; and the first capacitor has one terminal connected to the first terminal of the fourth transistor and the other terminal connected to the gate of the fourth transistor.

As another example, the second pulling up sub-circuit may comprise a fifth transistor and a second capacitor, wherein: the fifth transistor has a gate connected to the second node, a first terminal connected to the second voltage terminal and a second terminal connected to the second signal outputting terminal; and the second capacitor has one terminal connected to the first terminal of the fifth transistor and the other terminal connected to the gate of the fifth transistor.

As another example, when the first pulling up sub-circuit comprises the fourth transistor and the second pulling up sub-circuit comprises the fifth transistor, the fourth transistor may have a channel with a width-to-length ratio greater than that of the fifth transistor.

As another example, the first pulling down sub-circuit may comprise a sixth transistor and a third capacitor, wherein: the sixth transistor has a gate connected to the first node, a first terminal connected to the second clock signal terminal and a second terminal connected to the first signal outputting terminal; and the third capacitor has one terminal connected to the second terminal of the sixth transistor and the other terminal connected to the gate of the sixth transistor.

As another example, the second pulling down sub-circuit may comprise a seventh transistor and a fourth capacitor, wherein: the seventh transistor has a gate connected to the first node, a first terminal connected to the second clock signal terminal and a second terminal connected to the second signal outputting terminal; and the fourth capacitor has one terminal connected to the second terminal of the seventh transistor and the other terminal connected to the gate of the seventh transistor.

As another example, when the first pulling down sub-circuit comprises the sixth transistor and the second pulling down sub-circuit comprises the seventh transistor, the sixth transistor has a channel with a width-to-length ratio greater than that of the seventh transistor.

According to another aspect of the embodiments of the preset disclosure, a gate driving circuit is provided, which may comprise at least two stages of any of the above cascaded shift register units, wherein the signal inputting terminal of a first stage of shift register unit is configured to receive a starting signal; and each of the cascaded shift register units other than the first stage of shift register unit has its signal inputting terminal connected to the second signal outputting terminal of its previous stage of shift register unit.

According to another aspect of the embodiments of the preset disclosure, a display apparatus comprising any of the above gate driving circuits is provided.

According to another aspect of the embodiments of the preset disclosure, a method for driving a shift register unit is provided, comprising:

inputting the voltage at the signal inputting terminal to the first node by a first controlling sub-circuit, and applying the voltage outputted from the signal inputting terminal to a first pulling down controlling sub-circuit and a second pulling down controlling sub-circuit respectively; outputting the voltage at the first voltage terminal to the second node by the second controlling sub-circuit; outputting the voltage at the second voltage terminal to the first signal outputting terminal and the second signal outputting terminal by the first pulling down controlling sub-circuit and the second pulling down controlling sub-circuit, respectively; and outputting the voltage at the second clock signal terminal to the first signal outputting terminal and the second signal outputting terminal by the first pulling down controlling sub-circuit and a second pulling down controlling sub-circuit, respectively, during a first period for scanning a current image frame;

outputting the voltage at the second clock signal terminal to the first signal outputting terminal and the second signal outputting terminal by the first pulling down controlling sub-circuit and a second pulling down controlling sub-circuit, respectively; and outputting the voltage at the first clock signal terminal to the second node by the second controlling sub-circuit, during a second period; and

outputting the voltage at the signal inputting terminal to the first node by the first controlling sub-circuit, and outputting the voltage at the first voltage terminal to the second node by the second controlling sub-circuit; and outputting the voltage at the second voltage terminal to the first signal outputting terminal and the second signal outputting terminal by the first pulling up sub-circuit and the second pulling up sub-circuit, respectively, during a third period,

wherein during the second period and the third period, the controlling signals at the signal inputting terminal, the first clock signal terminal and the second clock signal terminal are applied repeatedly until starting a scanning of a next image frame, such that the first signal outputting terminal and the second signal outputting terminal keep in outputting the voltage at the second voltage terminal.

According to the embodiments of the disclosure, the first controlling sub-circuit may control a potential at the first node. Under the control of the potential at the first node, the voltage of the second clock signal terminal may be outputted to the first signal outputting terminal and the second signal outputting terminal by the first pulling down sub-circuit and the second pulling down sub-circuit. In addition, the first node, the first clock signal terminal and the second voltage terminal may be capable of controlling the potential at the second node through the second controlling sub-circuit. Under the control of the potential at the second node, the first pulling up sub-circuit and the second pulling up sub-circuit may be capable of outputting the voltage of the second voltage terminal to the first signal outputting terminal and the second signal outputting terminal, respectively.

### BRIEF DESCRIPTION OF THE DRAWINGS

In order to illustrate the embodiments of the disclosure or the conventional technical solution more clearly, drawings which are to be used in the description of the embodiments or the description of the conventional art will be briefly described. It will be apparent that the drawings in the following description are merely illustrative, and other drawings may be also obtained by those skilled in the art in view of the following drawings, without making a creative work.

FIG. 1 shows a structural schematic diagram illustrating a shift register unit according to an embodiment of the present disclosure;

FIG. 2 is a detailed structural schematic diagram illustrating respective sub-circuits in the shift register unit of FIG. 1;

FIG. 3 is a timing diagram of a controlling signal for controlling the shift register unit of FIG. 2; and

FIG. 4 is a structural schematic diagram illustrating a gate driving circuit composed of a plurality of cascaded shift register units of FIG. 2.

### DETAILED DESCRIPTION

The embodiments of the present disclosure will now be described in conjunction with the accompanying drawings. It will be apparent that the described embodiments are merely part of the embodiments of the disclosure and are not intended to be exhaustive. Other embodiments obtained based on the disclosed embodiments in the present disclosure by those of ordinary skill in the art without making a creative work are also within the scope of the present disclosure.

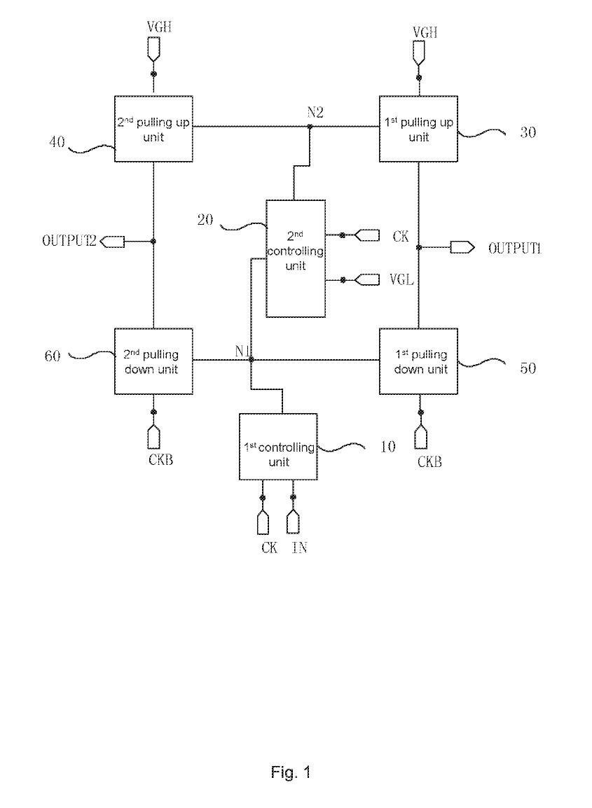

The embodiments of the present disclosure provide a shift register unit. As shown in FIG. 1, the shift register unit may comprise a first controlling sub-circuit 10, a second controlling sub-circuit 20, a first pulling up sub-circuit 30, a second pulling up sub-circuit 40, a first pulling down sub-circuit 50 and a second pulling down sub-circuit 60.

The first controlling sub-circuit 10 may be connected to a signal inputting terminal IN, a first clock signal terminal CK and a first node N1, and configured to output a voltage at the signal inputting terminal IN to the first node N1, under the control of a potential at the first clock signal terminal CK.

The second controlling sub-circuit 20 may be connected to the first clock signal terminal CK, a first voltage terminal VGL, the first node N1 and a second node N2, and configured to output a voltage at the first voltage terminal VGL to the second node N2 under the control of a potential at the first clock signal terminal CK, and/or output a voltage at the first clock signal terminal CK to the second node N2 under the control of a potential at the first node N1.

The first pulling up sub-circuit 30 may be connected to the second node N2, a second voltage terminal VGH and a first signal outputting terminal OUTPUT1, and configured to output a voltage at the second voltage terminal VGH to the first signal outputting terminal OUTPUT1 under the control of a potential at the second node N2.

The second pulling up sub-circuit 40 may be connected to the second node N2, the second voltage terminal VGH and a second signal outputting terminal OUTPUT1, and configured to output a voltage at the second voltage terminal VGH to the second signal outputting terminal OUTPUT2 under the control of a potential at the second node N2.

The first pulling down sub-circuit 50 may be connected to the first node N1, a second clock signal terminal CKB and the first signal outputting terminal OUTPUT1, and configured to output a voltage at the second clock signal terminal CKB to the first signal outputting terminal OUTPUT1 under the control of a potential at the first node N1.

The second pulling down sub-circuit may be connected to the first node N1, the second clock signal terminal CKB and the second signal outputting terminal OUTPUT2, and configured to output a voltage at the second clock signal terminal CKB to the second signal outputting terminal OUTPUT2 under the control of a potential at the first node N1.

Since the first controlling sub-circuit is capable of controlling the potential at the first node, the first pulling down sub-circuit and the second pulling down sub-circuit are capable of outputting the voltage of the second clock signal terminal to the first signal outputting terminal and the first signal outputting terminal, respectively. Furthermore, the first node, the first clock signal terminal and the second voltage terminal can control the potential at the second node through the second controlling sub-circuit. Under the control of the potential at the second node, the first pulling up sub-circuit and the second pulling up sub-circuit may output the potential at the second voltage terminal to the first signal outputting terminal and the second signal outputting terminal, respectively.

Accordingly, the voltage at the second voltage terminal can be outputted to the second signal outputting terminal through the second pulling up sub-circuit while being outputted to the first signal outputting terminal through the first pulling up sub-circuit. In addition, the voltage at the second clock signal terminal can be outputted to the second signal outputting terminal through the second pulling down sub-circuit while being outputted to the first signal outputting terminal through the first pulling down sub-circuit. Thus, signals outputted from the first signal outputting terminal and the second signal outputting terminal can be controlled independently by using different sub-circuits. In this case, if the first signal outputting terminal is connected to a gate line, and the second signal outputting terminal is connected to a signal inputting terminal of its next stage of shift register unit, even in a case that some stage of shift register unit is broken such that the first signal outputting terminal outputs abnormally, the second signal outputting terminal may output a signal to its next stage of shift register unit normally, thereby enabling the voltage outputted from a stage of broken shift register to its next stage of shift register unit being normal.

Hereinafter, a detailed description will now be made on a specific structure of respective sub-circuits in the above shift register unit.

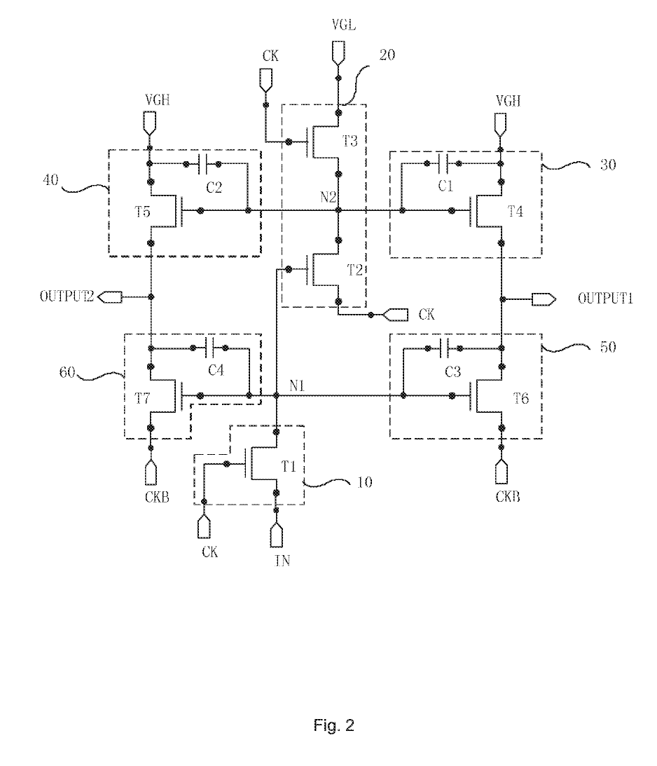

In particular, as shown in FIG. 2, the first controlling sub-circuit 10 may comprise a first transistor T1 having a gate connected to the first clock signal terminal CK, a first terminal connected to the signal inputting terminal IN, and a second terminal connected to the first node N1. The above first controlling sub-circuit 10 may further comprise a plurality of transistors which are connected with the first transistor T1 in parallel.

The second controlling sub-circuit 20 comprises a second transistor T2 and a third transistor T3. The second transistor T2 has a gate connected to the first node N1, a first terminal connected to the first clock signal terminal CK and a second terminal connected to the second node N2.

The third transistor T3 may have a gate connected to the first clock signal terminal CK, a first terminal connected to the first voltage terminal VGL and a second terminal connected to the second node N2. The above second controlling sub-circuit 20 may further comprise a plurality of transistors which are connected with the second transistor T2 in parallel and a plurality of transistors which are connected with the third transistor T3 in parallel.

The first pulling up sub-circuit 30 may comprise a fourth transistor T4 and a first capacitor C1. The fourth transistor T4 has a gate connected to the second node N2, a first terminal connected to the second voltage terminal VGH and a second terminal connected to the first signal outputting terminal OUTPUT1. The first capacitor C1 has one terminal connected to the first terminal of the fourth transistor T4 and the other terminal connected to the gate of the fourth transistor T4. The above first pulling up sub-circuit 30 may further comprise a plurality of transistors which are connected with the fourth transistor T4 in parallel.

The second pulling up sub-circuit 40 comprises a fifth transistor T5 and a second capacitor C2. The fifth transistor T has a gate connected to the second node N2, a first terminal connected to the second voltage terminal VGH and a second terminal connected to the second signal outputting terminal OUTPUT2. The second capacitor C2 has one terminal connected to the first terminal of the fifth transistor T5 and the other terminal connected to the gate of the fifth transistor T5. The above second pulling up sub-circuit 40 may further comprise a plurality of transistors which are connected with the fifth transistor T5 in parallel.

Further, in the case where the first signal outputting terminal OUTPUT1 is connected to the gate line in the display panel and the second signal outputting terminal OUTPUT2 is configured to be connected with the signal inputting terminal IN of the next stage of shift register unit, the signal outputted from the first pulling up sub-circuit 30 is used to drive the gate line (requiring a strong driving force), and the signal outputted from the second pulling up sub-circuit 40 is to be transmitted to the next stage of shift register unit without driving a large load. Therefore, when the first pulling up sub-circuit 30 includes the fourth transistor T4 and the second pulling up sub-circuit 40 includes the fifth transistor T5, the fourth transistor T4 has a channel with a width-to-length ratio W/L greater than that of the fifth transistor T5. In this way, the fifth transistor T5 can occupy a smaller layout space, which is facilitated to a narrow bezel design of the display panel.

The first pulling down sub-circuit 50 comprises a sixth transistor T6 and a third capacitor C3. The sixth transistor T6 has a gate connected to the first node N1, a first terminal connected to the second clock signal terminal CKB and a second terminal connected to the first signal outputting terminal OUTPUT1. The third capacitor C3 has one terminal connected to the second terminal of the sixth transistor T6 and the other terminal connected to the gate of the sixth transistor T6. The above first pulling down sub-circuit 50 may further comprise a plurality of transistors which are connected with the sixth transistor T6 in parallel.

The second pulling down sub-circuit 60 comprises a seventh transistor T7 and a fourth capacitor C4. The seventh transistor T4 has a gate connected to the first node N1, a first terminal connected to the second clock signal terminal CKB and a second terminal connected to the second signal outputting terminal OUTPUT2. The fourth capacitor C4 has one terminal connected to the second terminal of the seventh transistor T7 and the other terminal connected to the gate of the seventh transistor T7. The above second pulling down sub-circuit may further comprise a plurality of transistors which are connected with the seventh transistor T7 in parallel.

Further, in the case where the first signal outputting terminal OUTPUT1 is connected to the gate line in the display panel and the second signal outputting terminal OUTPUT2 is configured to be connected with the signal inputting terminal IN of the next stage of shift register unit, the signal outputted from the first pulling down sub-circuit 50 is used to drive the gate line (requiring a strong driving force), and the signal outputted from the second pulling down sub-circuit 60 is to be transmitted to the next stage of shift register unit without driving a large load. Therefore, when the first pulling down sub-circuit 50 includes the sixth transistor T6 and the second pulling down sub-circuit 60 includes the seventh transistor T7, the sixth transistor T6 has a channel with a width-to-length ratio W/L greater than that of the seventh transistor T7. In this way, the seventh transistor T7 can occupy a smaller layout space, which is facilitated to a narrow bezel design of the display panel.

It should be noted that each transistor in the above sub-circuits may be a P type transistor or an N-type transistor, which is not limited thereto. In addition, the first terminal of the above transistors may be a source and the second terminal may be a drain. Alternatively, the first terminal of the above transistors may be a drain while the second terminal may be a source. The present disclosure is not limited thereto.

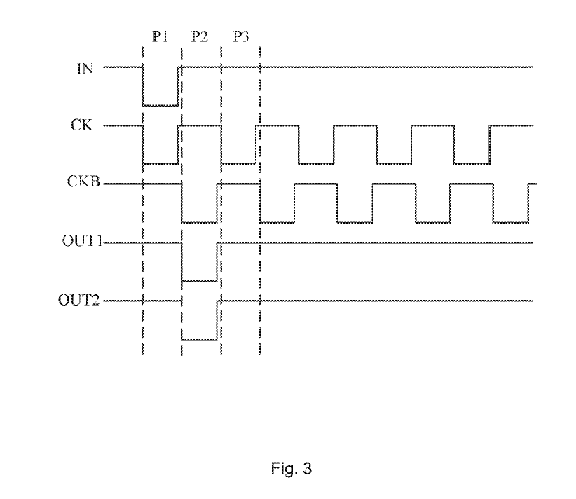

The operation of the shift register unit shown in FIG. 2 on an image frame will be described in detail below with reference to FIG. 3. Hereinafter, it is assumed that the transistors of the shift register unit shown in FIG. 2 are all P-type transistors. In addition, the first voltage terminal VGL in the embodiment of the present disclosure may output at a low level or may be grounded, and the second voltage terminal VGH may output at a high level.

During a first period P1 for an image frame, IN=0, CK=0 and CKB=1, wherein “0” indicates for a low level, and “1” indicates for a high level.

In particular, when the first clock signal terminal CK inputs a low level, the first transistor T1 is turned on. The low level inputted from the signal inputting terminal IN is outputted to the first node N1 through the first transistor T1, and then the low level at the first node N1 is stored by the third capacitor C3 and the fourth capacitor C4.

Under the control of the potential at the first node N1, the sixth transistor T6 and the seventh transistor T7 are turned on. At this time, the high level of the second clock signal terminal CKB is output to the first signal outputting terminal OUTPUT1 and the second signal outputting terminal OUTPUT2 through the sixth transistor T6 and the seventh transistor T7, respectively.

In addition, under the control of the potential at the first node N1, the second transistor T2 is turned on, and the low level of the first clock signal terminal CK is outputted to the second node N2. Under the control of the first clock signal terminal CK, the third transistor T3 is turned on, and the low level of the first voltage terminal VGL is outputted to the second node N2. Under the control of the potential at the second node N2, the fourth transistor T4 and the fifth transistor T5 are turned on. At this time, the high level of the second voltage terminal VGH is outputted to the first signal outputting terminal OUTPUT1 and the second signal outputting terminal OUTPUT2 through the fourth transistor T4 and the fifth transistor T5, respectively.

Thus, at this period, the first signal outputting terminal OUTPUT1 and the second signal outputting terminal OUTPUT2 both output at a high level.

During a second period P2 of the image frame, IN=1, CK=1 and CKB=1.

In particular, when the first clock signal terminal CK outputs a high level, the first transistor T1 is turned off, and the third capacitor C3 and the fourth capacitor C4 may output the low level stored during the previous period to the first node N1, such that the first node N1 remains at the low level. In this way, the sixth transistor T6 and the seventh transistor T7 are turned on, and the low level of the second clock signal terminal CKB is output to the first signal outputting terminal OUTPUT1 and the second signal outputting terminal OUTPUT2 through the sixth transistor T6 and the seventh transistor T7, respectively.

Under the control of the potential at the first clock signal terminal CK, the third transistor T3 is turned off. Under the control of the potential at the first node N1, the second transistor T2 is turned on, and the high level of the first clock signal terminal CK is outputted to the second node N2. At this time, the fourth transistor T4 and the fifth transistor T5 are turned off under the control of the potential at the second node N2.

Thus, at this period, the first signal outputting terminal OUTPUT1 and the second signal outputting terminal OUTPUT2 both output at a low level.

During a third period P3 of the image frame, IN=1, CK=0 and CKB=1.

Under the control of the potential at the first clock signal terminal CK, the first transistor is turned on, and the low level of the signal inputting terminal IN is outputted to the first node N1. Under the control of the potential at the first node N1, the sixth transistor T6 and the seventh transistor T7 are turned off.

In addition, under the control of the potential at the first node N1, the second transistor T2 is turned off. Under the control of the potential at the first clock signal terminal CK, the low level of the first voltage terminal VGL is outputted to the second node N2. The fourth transistor T4 and the fifth transistor T5 are turned on under the control of the potential at the second node N2. In this case, the high level of the second voltage terminal VGH is outputted to the first signal outputting terminal OUTPUT1 and the second signal outputting terminal OUTPUT2 through the fourth transistor T4 and the fifth transistor T5, respectively.

Thus, at this period, the first signal outputting terminal OUTPUT1 and the second signal outputting terminal OUTPUT2 both output at a high level.

It should be noted that the controlling signals at the signal inputting terminal IN, the first clock signal terminal CK and the second clock signal terminal CKB during the second period and the third period are applied repeatedly until starting a scanning of a next image frame, such that the first signal outputting terminal OUTPUT1 and the second signal outputting terminal OUTPUT2 keep in outputting the voltage at the second voltage terminal VGH.

Further, when all of transistors in the shift register unit shown in FIG. 2 are N-type transistors, the waveforms of the controlling signals shown in FIG. 3 should be turned over. In other words, sub-circuits connected to the first voltage terminal VGL in FIG. 1 and transistors connected to the first voltage terminal VGL in FIG. 2 are connected to the second voltage terminal VGH, and sub-circuits connected to the second voltage terminal VGH in FIG. 1 and transistors connected to the second voltage terminal VGH in FIG. 2 are connected to the first voltage terminal VGL. The operation of the shift register unit is the same as above, which will not be discussed any more.

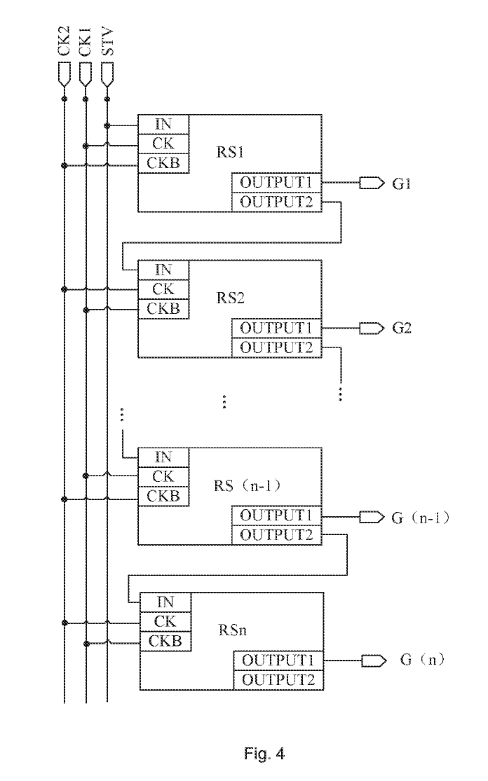

An embodiment of the present disclosure may provide a gate driving circuit. As shown in FIG. 4, the gate driving circuit may comprise at least two stages of any of the above cascaded shift register units. The first signal outputting terminals OUTPUT1 of respective stage of the shift register unit are connected to the gate lines (G1, G2, . . . , G(n−1), G(n)) in turn, so as to perform a progressive scanning on the gate lines. The shift register units in the gate driving circuit have a structure and effects as same as the shift register units according to the above embodiments. Since the description on the structure and effects of the shift register units has been discussed in detail in the above embodiments, it will not be discussed herein.

In particular, the signal inputting terminal IN of the first stage of shift register unit RS1 may be used to receive a starting signal STV.

Each of the cascaded shift register units (RS2, . . . , RS(n−1)) other than the first stage of shift register unit RS1 has its signal inputting terminal IN connected to the second signal outputting terminal OUTPUT2 of its previous stage of shift register unit. The last stage of shift register unit RS has a floated second signal outputting terminal OUTPUT2. The first clock signal terminal CK and the second clock signal terminal CKB connects a clock signal CK1 and a clock signal CK2 alternately one by one.

Another embodiment of the present disclosure provides a display apparatus comprising the gate driving circuit as discussed above, which has a structure and effects as same as the gate driving circuit according to the above embodiments. Since the description on the structure and effects of the gate driving circuit has been discussed in detail in the above embodiments, it will not be discussed herein.

It should be noted that the display apparatus according to the embodiments of the disclosure may be a liquid crystal display device or an organic light emitting diode display apparatus. For example, the display apparatus may be a liquid crystal display, a liquid crystal TV, a digital frame, a cell phone, a tablet, and a product or a component having a displaying function.

Another embodiment of the present disclosure provides a method for driving a shift register unit, during scanning of an image frame, the method may comprise the following steps.

During the first period P1, under the control of the potential at the first clock signal terminal CK, a first controlling sub-circuit 10 may input the voltage at the signal inputting terminal IN to the first node N1, and apply the voltage outputted from the signal inputting terminal IN to a first pulling down controlling sub-circuit 50 and a second pulling down controlling sub-circuit 60 respectively. The voltage at the first voltage terminal CK is outputted to the second node N2 by the second controlling sub-circuit 20, under the control of the potential at the first node N1 and the potential at the first clock signal terminal CK.

In particular, when the first clock signal terminal CK inputs a low level, the first transistor T1 is turned on. The low level inputted from the signal inputting terminal IN is outputted to the first node N1 through the first transistor T1, and then the low level at the first node N1 is stored by the third capacitor C3 and the fourth capacitor C4. In addition, under the control of the potential at the first node N1, the second transistor T2 is turned on, and the low level of the first clock signal terminal CK is outputted to the second node N2. Under the control of the first clock signal terminal CK, the third transistor T3 is turned on, and the low level of the first voltage terminal VGL is outputted to the second node N2.

Under the control of the potential at the second node N2, the voltage at the second voltage terminal VGH is outputted to the first signal outputting terminal OUTPUT1 and the second signal outputting terminal OUTPUT2 by the first pulling down controlling sub-circuit 50 and the second pulling down controlling sub-circuit 60, respectively.

In particular, under the control of the potential at the second node N2, the fourth transistor T4 and the fifth transistor T5 are turned on. At this time, the high level of the second voltage terminal VGH is outputted to the first signal outputting terminal OUTPUT1 and the second signal outputting terminal OUTPUT2 through the fourth transistor T4 and the fifth transistor T5, respectively.

Under the control of the potential at the first node N1, the voltage at the second clock signal terminal CKB is outputted to the first signal outputting terminal OUTPUT1 and the second signal outputting terminal OUTPUT2 by the first pulling down controlling sub-circuit 50 and a second pulling down controlling sub-circuit 60, respectively.

In particular, under the control of the potential at the first node N1, the sixth transistor T6 and the seventh transistor T7 are turned on. At this time, the high level of the second clock signal terminal CKB is output to the first signal outputting terminal OUTPUT1 and the second signal outputting terminal OUTPUT2 through the sixth transistor T6 and the seventh transistor T7, respectively.

Thus, at this period, the first signal outputting terminal OUTPUT1 and the second signal outputting terminal OUTPUT2 both output at a high level.

During the second period P2, under the voltage stored during the previous period, the voltage at the second clock signal terminal CKB is outputted to the first signal outputting terminal OUTPUT1 and the second signal outputting terminal OUTPUT2 by the first pulling down controlling sub-circuit 50 and a second pulling down controlling sub-circuit 60, respectively.

In particular, the third capacitor C3 and the fourth capacitor C4 may output the low level stored during the previous periods to the first node N1, such that the first node N1 remains at the low level. In this way, the sixth transistor T6 and the seventh transistor T7 are turned on, and the low level of the second clock signal terminal CKB is outputted to the first signal outputting terminal OUTPUT1 and the second signal outputting terminal OUTPUT2 through the sixth transistor T6 and the seventh transistor T7, respectively.

The first node N1 remains at the voltage of previous periods, and the voltage at the first clock signal terminal CK is outputted to the second node N2 by the second controlling sub-circuit 20.

In particular, under the control of the potential at the first clock signal terminal CK, the third transistor T3 is turned off. Under the control of the potential at the first node N1, the second transistor T2 is turned on, and the high level of the first clock signal terminal CK is outputted to the second node N2.

The first controlling sub-circuit 10, the first pulling up sub-circuit 30 and the second pulling up sub-circuit 40 output no signal. In particular, the first clock signal terminal CK outputs at a high level, the first transistor T1 is turned off. The fourth transistor T4 and the fifth transistor T5 are turned off under the control of the potential at the second node N2.

Thus, at this period, the first signal outputting terminal OUTPUT1 and the second signal outputting terminal OUTPUT2 both output at a low level.

During the third period P3, under the control of the first clock signal terminal CK, the voltage at the signal inputting terminal IN is outputted to the first node N1 by the first controlling sub-circuit 10. The voltage at the first voltage terminal VGL is outputted to the second node N2 by the second controlling sub-circuit 20, under the control of the potential at the first node N1 and the potential at the first clock signal terminal CK.

In particular, under the control of the potential at the first clock signal terminal CK, the first transistor T1 is turned on, and the low level of the signal inputting terminal IN is outputted to the first node N1. Under the control of the potential at the first node N1, the second transistor T2 is turned off. Under the control of the potential at the first clock signal terminal CK, the low level of the first voltage terminal VGL is outputted to the second node N2.

Under the control of the second node N2, the voltage at the second voltage terminal VGH is outputted to the first signal outputting terminal OUTPUT1 and the second signal outputting terminal OUTPUT2 by the first pulling up sub-circuit 30 and the second pulling up sub-circuit 40, respectively.

In particular, the fourth transistor T4 and the fifth transistor T5 are turned on under the control of the potential at the second node N2. In this case, the high level of the second voltage terminal VGH is outputted to the first signal outputting terminal OUTPUT1 and the second signal outputting terminal OUTPUT2 through the fourth transistor T4 and the fifth transistor T5, respectively.

The first pulling down sub-circuit 50 and the second pulling down sub-circuit 60 may output no signal.

In particular, under the control of the potential at the first node N1, the sixth transistor T6 and the seventh transistor T7 are turned off.

Thus, at this period, the first signal outputting terminal OUTPUT1 and the second signal outputting terminal OUTPUT2 both output at a high level.

It should be noted that the controlling signals at the signal inputting terminal IN, the first clock signal terminal CK and the second clock signal terminal CKB during the second period and the third period are applied repeatedly until starting a scanning of a next image frame, such that the first signal outputting terminal OUTPUT1 and the second signal outputting terminal OUTPUT2 keep in outputting the voltage at the second voltage terminal VGH.

It will be apparent to those skilled in the art that various modifications and variations can be made in the embodiments of the disclosure without departing from the spirit and scope of the embodiments of the disclosure. In this way, the present disclosure is intended to embrace such modifications and variations if these modifications and variations of the embodiments of the disclosure are within the scope of the appended claims and their equivalents.

1. A shift register unit, comprising:
a first controlling sub-circuit, connected to a signal inputting terminal, a first clock signal terminal and a first node, and configured to output a voltage at the signal inputting terminal to the first node, under the control of a potential at the first clock signal terminal;
a second controlling sub-circuit, connected to the first clock signal terminal, a first voltage terminal, the first node and a second node, and configured to output a voltage at the first voltage terminal to the second node under the control of a potential at the first clock signal terminal, and/or output a voltage at the first clock signal terminal to the second node under the control of a potential at the first node;
a first pulling up sub-circuit, connected to the second node, a second voltage terminal and a first signal outputting terminal, and configured to output a voltage at the second voltage terminal to the first signal outputting terminal under the control of a potential at the second node;
a second pulling up sub-circuit, connected to the second node, the second voltage terminal and a second signal outputting terminal, and configured to output a voltage at the second voltage terminal to the second signal outputting terminal under the control of a potential at the second node;
a first pulling down sub-circuit, connected to the first node, a second clock signal terminal and the first signal outputting terminal, and configured to output a voltage at the second clock signal terminal to the first signal outputting terminal under the control of a potential at the first node; and
a second pulling down sub-circuit, connected to the first node, the second clock signal terminal and the second signal outputting terminal, and configured to output a voltage at the second clock signal terminal to the second signal outputting terminal under the control of a potential at the first node.

2. The shift register unit of claim 1, wherein the first controlling sub-circuit comprises a first transistor having a gate connected to the first clock signal terminal, a first terminal connected to the signal inputting terminal, and a second terminal connected to the first node.

3. The shift register unit of claim 1, wherein the second controlling unit comprises a second transistor and a third transistor, wherein:
the second transistor has a gate connected to the first node, a first terminal connected to the first clock signal terminal and a second terminal connected to the second node; and
the third transistor has a gate connected to the first clock signal terminal, a first terminal connected to the first voltage terminal and a second terminal connected to the second node.

4. The shift register unit of claim 1, wherein the first pulling up sub-circuit comprises a fourth transistor and a first capacitor, wherein:
the fourth transistor has a gate connected to the second node, a first terminal connected to the second voltage terminal and a second terminal connected to the first signal outputting terminal; and
the first capacitor has one terminal connected to the first terminal of the fourth transistor and the other terminal connected to the gate of the fourth transistor.

5. The shift register unit of claim 1, wherein the second pulling up sub-circuit comprises a fifth transistor and a second capacitor, wherein:
the fifth transistor has a gate connected to the second node, a first terminal connected to the second voltage terminal and a second terminal connected to the second signal outputting terminal; and
the second capacitor has one terminal connected to the first terminal of the fifth transistor and the other terminal connected to the gate of the fifth transistor.

6. (canceled)

7. The shift register unit of claim 1, wherein the first pulling down sub-circuit comprises a sixth transistor and a third capacitor, wherein:
the sixth transistor has a gate connected to the first node, a first terminal connected to the second clock signal terminal and a second terminal connected to the first signal outputting terminal; and
the third capacitor has one terminal connected to the second terminal of the sixth transistor and the other terminal connected to the gate of the sixth transistor.

8. The shift register unit of claim 1, wherein the second pulling down sub-circuit comprises a seventh transistor and a fourth capacitor, wherein:
the seventh transistor has a gate connected to the first node, a first terminal connected to the second clock signal terminal and a second terminal connected to the second signal outputting terminal; and
the fourth capacitor has one terminal connected to the second terminal of the seventh transistor and the other terminal connected to the gate of the seventh transistor.

9. (canceled)

10. A gate driving circuit comprising at least two stages of cascaded shift register units of claim 1,
wherein the signal inputting terminal of a first stage of shift register unit is configured to receive a starting signal; and
each of the cascaded shift register units other than the first stage of shift register unit has its signal inputting terminal connected to the second signal outputting terminal of its previous stage of shift register unit.

11. A display apparatus comprising the gate driving circuit of claim 10.

12. A method for driving the shift register unit of claim 1, comprising:
inputting the voltage at the signal inputting terminal to the first node by the first controlling sub-circuit, and applying the voltage outputted from the signal inputting terminal to the first pulling down sub-circuit and the second pulling down sub-circuit respectively; outputting the voltage at the first voltage terminal to the second node by the second controlling sub-circuit; outputting the voltage at the second voltage terminal to the first signal outputting terminal and the second signal outputting terminal by the first pulling down sub-circuit and the second pulling down sub-circuit, respectively; and outputting the voltage at the second clock signal terminal to the first signal outputting terminal and the second signal outputting terminal by the first pulling down sub-circuit and the second pulling down sub-circuit, respectively, during a first period for scanning a current image frame;
outputting the voltage at the second clock signal terminal to the first signal outputting terminal and the second signal outputting terminal by the first pulling down sub-circuit and the second pulling down sub-circuit, respectively; and outputting the voltage at the first clock signal terminal to the second node by the second sub-circuit, during a second period; and
outputting the voltage at the signal inputting terminal to the first node by the first sub-circuit, and outputting the voltage at the first voltage terminal to the second node by the second sub-circuit; and
outputting the voltage at the second voltage terminal to the first signal outputting terminal and the second signal outputting terminal by the first pulling up sub-circuit and the second pulling up sub-circuit, respectively, during a third period,
wherein during the second period and the third period, the controlling signals at the signal inputting terminal, the first clock signal terminal and the second clock signal terminal are applied repeatedly until starting a scanning of a next image frame, such that the first signal outputting terminal and the second signal outputting terminal keep outputting the voltage at the second voltage terminal.

13. The shift register unit of claim 2, wherein the second sub-circuit comprises a second transistor and a third transistor, wherein:
the second transistor has a gate connected to the first node, a first terminal connected to the first clock signal terminal and a second terminal connected to the second node; and
the third transistor has a gate connected to the first clock signal terminal, a first terminal connected to the first voltage terminal and a second terminal connected to the second node.

14. The shift register unit of claim 2, wherein the first pulling up sub-circuit comprises a fourth transistor and a first capacitor, wherein:
the fourth transistor has a gate connected to the second node, a first terminal connected to the second voltage terminal and a second terminal connected to the first signal outputting terminal; and
the first capacitor has one terminal connected to the first terminal of the fourth transistor and the other terminal connected to the gate of the fourth transistor.

15. The shift register unit of claim 3, wherein the first pulling up sub-circuit comprises a fourth transistor and a first capacitor, wherein:
the fourth transistor has a gate connected to the second node, a first terminal connected to the second voltage terminal and a second terminal connected to the first signal outputting terminal; and
the first capacitor has one terminal connected to the first terminal of the fourth transistor and the other terminal connected to the gate of the fourth transistor.

16. The shift register unit of claim 4, wherein the second pulling up sub-circuit comprises a fifth transistor and a second capacitor, wherein:
the fifth transistor has a gate connected to the second node, a first terminal connected to the second voltage terminal and a second terminal connected to the second signal outputting terminal; and
the second capacitor has one terminal connected to the first terminal of the fifth transistor and the other terminal connected to the gate of the fifth transistor.

17. The shift register unit of claim 16, wherein the fourth transistor has a channel with a width-to-length ratio greater than that of the fifth transistor.

18. The shift register unit of claim 7, wherein the second pulling down sub-circuit comprises a seventh transistor and a fourth capacitor, wherein:
the seventh transistor has a gate connected to the first node, a first terminal connected to the second clock signal terminal and a second terminal connected to the second signal outputting terminal; and
the fourth capacitor has one terminal connected to the second terminal of the seventh transistor and the other terminal connected to the gate of the seventh transistor.

19. The shift register unit of claim 18, wherein the sixth transistor has a channel with a width-to-length ratio greater than that of the seventh transistor.
